(19) United States
(12) Patent Application Publication
(10) Pub. No.: US 2014/0145348 A1
(43) Pub. Date: May 29, 2014

(54) RF (RADIO FREQUENCY) MODULE AND METHOD OF MAUFACTURING THE SAME

(71) Applicant: SAMSUNG ELECTRO-MECHANICS CO., LTD., Suwon-si (KR)

(72) Inventor: Seung Yong CHOI, Suwon-si (KR)

(73) Assignee: SAMSUNG ELECTRO-MECHANICS CO., LTD., Suwon-si (KR)

(21) Appl. No.: 14/087,827

(22) Filed: Nov. 22, 2013

(30) Foreign Application Priority Data
Nov. 26, 2012 (KR) 10-2012-0134455

(51) Int. Cl. H01L 25/065; H01L 23/00

(52) U.S. Cl. CPC H01L 25/0657; H01L 24/95
USPC 257/774; 438/107

(57) ABSTRACT

Disclosed herein are an RF module and a method of manufacturing the same. According to the exemplary embodiment of the present invention, the RF module includes: an RF IC device provided with a via through which upper and lower surfaces thereof are connected to each other; an electronic component mounted on the upper surface or the lower surface of the RF IC device; a molding material having the electronic component sealed therein to protect the electronic component and formed on the upper or lower surface of the RF IC device; and an auxiliary substrate coupled with the upper or lower surface of the RF IC device and providing a place at which other electronic components other than the electronic component sealed in the molding material are mounted, wherein the auxiliary substrate is provided with a through hole having a predetermined size to mount the other electronic components therein.

This application claims the benefit under 35 U.S.C. Section 119 of Korean Patent Application Serial No. 10-2012-0134455 entitled “RF (Radio Frequency) Module And Method Of Manufacturing The Same” filed on Nov. 26, 2012, which is hereby incorporated by reference in its entirety into this application.

### BACKGROUND OF THE INVENTION

1. Technical Field

The present invention relates to an RF module and a method of manufacturing the same, and more particularly, to an RF module capable of designing an IC circuit of a wafer level chip scale package (WLCSP) and designing an input/output (I/O) pitch with a sufficient degree of freedom and a method of manufacturing the same.

2. Description of the Related Art

In an RF module which has been used in cellular phones, and the like, a high frequency characteristic is very important. A portion most sensitive to the high frequency characteristics is a wiring between a semiconductor (LSI) chip terminal and external components. According to the related art, the wiring becomes LSI chip bonding wire-package substrate-post electrode-component terminal and thus becomes long. In the case of the RF module, it is preferable that the number of wirings in the module is increased in the module and the number of external connection terminals in the module is decreased. In a general module technology, a substrate side of a package may adopt a multilayer wiring and a large number of wirings, but a post electrode side is generally difficult to adopt a large number of wirings. Further, a signal path also has a two-dimensional structure. When the signal path has a three-dimensional structure, the signal path may be short as much and the high frequency characteristic may also be improved. Further, a mounting area may also be decreased and thus a price of product may be decreased. For this reason, when the signal path is mounted three-dimensionally, it is required to shorten the signal path.

FIG. 1 is a diagram illustrating an RF module having a PoP structure in which a semiconductor package is stacked on the WLCSP according to the related art.

Referring to FIG. 1, in the RF module according to the related art, an I/O is formed as a TSV 134 of a WLCSP 126, a package on package (POP) structure is formed using a bump 148, or interconnection with the outside is formed. Further, the RF module has a structure in which devices are further mounted on upper and lower surfaces of a semiconductor die (IC) 122 and are interconnected by the TSV 134. In this case, a height of a bump 148 is larger than that of a device 140 mounted on the semiconductor die (IC) 122, such that it is difficult to form a fine pitch. As a result, a degree of freedom of a circuit design may be restricted.

### RELATED ART DOCUMENT

### Patent Document

(Patent Document 1) US Patent Laid-Open Publication No. US 2011/0215458

(Patent Document 2) Korean Patent Laid-Open Publication No. 10-2011-0002074

(Patent Document 3) Japanese Patent Laid-Open Publication No. 2007-273982

### SUMMARY OF THE INVENTION

An object of the present invention is to provide an RF module capable of designing an IC circuit of a wafer level chip scale package (WLCSP) and a designing an I/O pitch with a sufficient degree of freedom by allowing an RF IC device to perform a function of a main circuit substrate and introducing an auxiliary substrate to secure flexibility of I/O implementation and a method of manufacturing the same.

According to an exemplary embodiment of the present invention, there is provided an RF module, including: an RF IC device serving as a main substrate and provided with a via through which upper and lower surfaces thereof are connected to each other; an electronic component mounted on the upper surface or the lower surface of the RF IC device; a molding material having the electronic component sealed therein to protect the electronic component and formed on the upper surface or the lower surface of the RF IC device; and an auxiliary substrate coupled with the upper surface or the lower surface of the RF IC device and providing a place at which other electronic components other than the electronic component sealed in the molding material are mounted.

The auxiliary substrate may be provided with a through hole having a predetermined size to mount the other electronic components therein.

According to another exemplary embodiment of the present invention, there is provided a method of manufacturing an RF module, including: a) preparing an RF IC device serving as a main substrate; b) forming a via hole, through which upper and lower surfaces of the RF IC device are connected to each other, in the RF IC device and filling the via hole with a conductive material; c) forming metal wiring layers on both surfaces of the RF IC device, respectively, to be connected to the via hole; d) mounting an electronic component on the metal wiring layer of one side of the RF IC device; e) molding the one side of the RF IC device, on which the electronic component is mounted, with a molding material; f) coupling an auxiliary substrate provided with a through hole having a predetermined size to mount other electronic components therein with the other surface of the RF IC device; and g) mounting the other electronic components on the other surface of the RF IC device through the through hole of the auxiliary substrate.

In the step b), the via hole may be formed by dry etching using excimer laser or CO₂ laser.

In the step b), the conductive material filled in the via hole may be copper or silver.

The copper may be filled in the via hole by electroplating.

The method of manufacturing an RF module may further include: in order to mount the electronic component on the metal wiring layer of the one side of the RF IC device in the step d), forming a bump on the metal wiring layer of the one side of the RF IC device.

The molding material in the step e) may be a thermosetting resin or a thermoplastic resin.

The method of manufacturing an RF module may further include: in order to couple the auxiliary substrate with the other surface of the RF IC device in the step f), forming the bump on the metal wiring layer of the other surface of the RF IC device.

The method of manufacturing an RF module may further include: in order to mount the other electronic components on the other surface of the RF IC device in the step g), forming the bump on the metal wiring layer of the other surface of the RF IC device corresponding to a region of the through hole of the auxiliary substrate.

### BRIEF DESCRIPTION OF THE DRAWINGS

FIG. 1 is a diagram illustrating an RF module having a PoP structure in which a semiconductor package is stacked on the WLCSP according to the related art.

FIG. 2 is a diagram illustrating a structure of an RF module according to an exemplary embodiment of the present invention.

FIG. 3 is a plan view of an auxiliary substrate of the RF module of FIG. 2.

FIG. 4 is a flow chart illustrating an execution process of a method of manufacturing an RF module according to an exemplary embodiment of the present invention.

FIGS. 5A to 5E are diagrams sequentially illustrating a process of manufacturing the RF module according to the method of manufacturing an RF module according to the exemplary embodiment of the present invention.

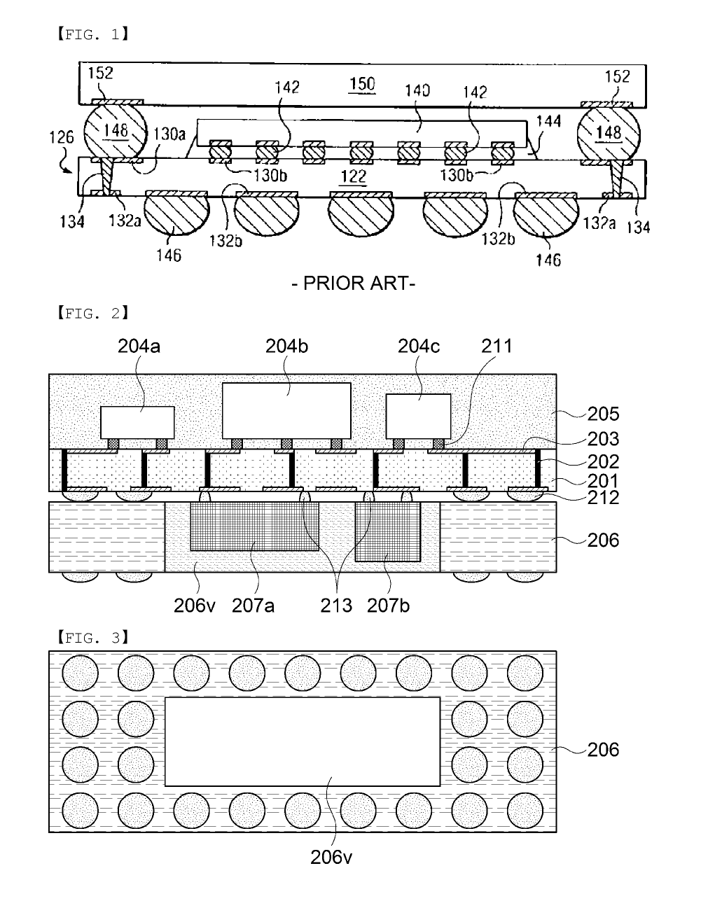

### DESCRIPTION OF THE PREFERRED EMBODIMENTS

Terms and words used in the present specification and claims are not to be construed as a general or dictionary meaning, but are to be construed to meaning and concepts meeting the technical ideas of the present invention based on a principle that the inventors can appropriately define the concepts of terms in order to describe their own inventions in the best mode.

Throughout the present specification, unless explicitly described to the contrary, “comprising” any components will be understood to imply the inclusion of other elements rather than the exclusion of any other elements. A term “part”, “ . . . er” “module”, “device”, or the like, described in the specification means a unit of processing at least one function or operation and may be implemented by hardware or software or a combination of hardware and software.

Hereinafter, exemplary embodiments of the present invention will be described in detail with reference to the accompanying drawings.

FIG. 2 is a diagram illustrating a structure of an RF module according to an exemplary embodiment of the present invention.

Referring to FIG. 2, the RF module according to the exemplary embodiment of the present invention is configured to include an RF IC device 201, electronic components 204a to 204c, a molding material 205, and an auxiliary substrate 206.

The RF IC device 201 serves as a main substrate and the inside thereof is provided with vias 202 through which upper and lower surfaces thereof are connected to each other.

The electronic components 204a to 204c are mounted on the upper surface or the lower surface of the RF IC device 201. The electronic components 204a to 204c may include semiconductor chips, ICs, and the like.

The molding material 205 is formed on the upper surface or the lower surface (that is, a surface on which electronic components are mounted) of the RF IC device 201 so that the molding material 205 has the electronic components 204a to 204c sealed therein to protect the electronic components 204a to 204c. Herein, as the molding material 205 as described above, a thermosetting resin or a thermoplastic resin may be used.

The auxiliary substrate 206 is coupled on the upper surface or the lower surface of the RF IC device 201 and provides a place at which other electronic components 207a and 207b other than the electronic components 204a to 204c sealed in the molding material 205 are mounted.

Herein, as illustrated in FIG. 3, the auxiliary substrate 206 is provided with a through hole 206v having a predetermined size to mount the other electronic components 207a and 207b therein. Similarly, the other electronic components 207a and 207b may also include semiconductor chips, ICs, and the like. In FIG. 2, reference numeral 203 represents a metal wiring layer and reference numerals 211, 212, and 213 each represent bumps.

Next, a process of manufacturing an RF module according to an exemplary embodiment of the present invention having a configuration as described above will be described.

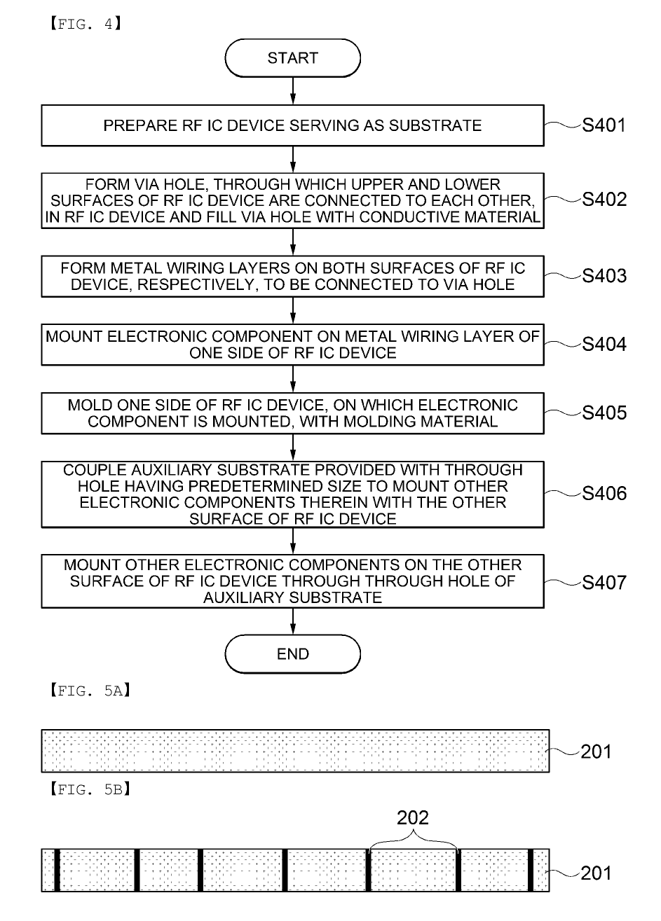

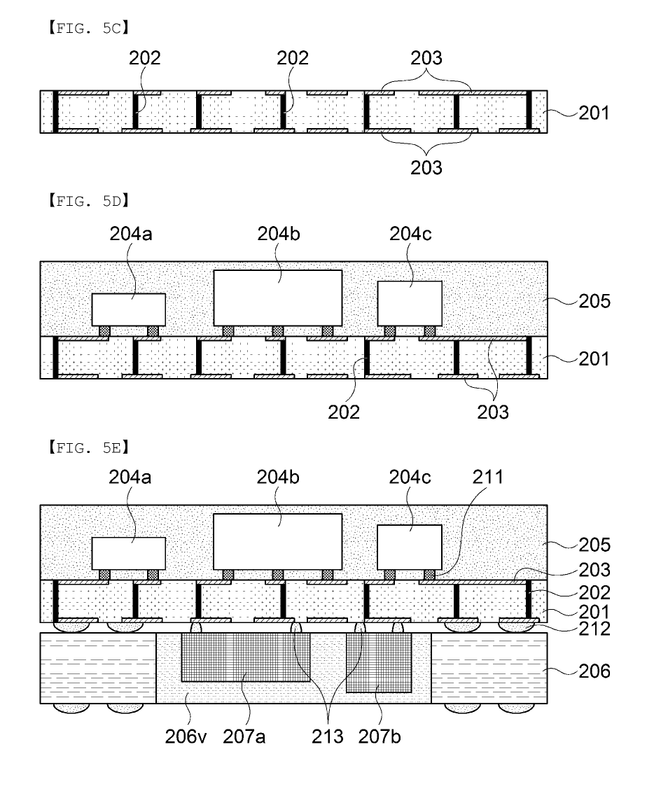

FIG. 4 is a flow chart illustrating an execution process of a method of manufacturing an RF module according to an exemplary embodiment of the present invention and FIGS. 5A to 5E are diagrams sequentially illustrating a process of manufacturing the RF module according to the method of manufacturing an RF module according to the exemplary embodiment of the present invention.

Referring to FIGS. 4 and 5A, according to the method of manufacturing an RF module according to the exemplary embodiment of the present invention, the RF IC device 201 serving as the main substrate is first prepared (S401). Herein, as the RF IC device 201, a silicon IC device may be used.

When the preparation of the RF IC device 201 is completed, as illustrated in FIG. 5B, the via hole 202 through which the upper surface and the lower surface of the RF IC device 201 are connected to each other is formed in the RF IC device 201 and is filled with a conductive material (S402).

Herein, the via hole 202 may be formed by dry etching or wet etching, but is preferably formed by dry etching using excimer laser or CO₂ laser. Further, as the conductive material filled in the via hole 202, copper or silver may be used. In this case, the copper may be filled in the via hole 202 by electroplating.

As described above, when the formation of the via hole 202 and the filling of the conductive material are completed, as illustrated in FIG. 5C, the metal wiring layers 203 are each formed on both surfaces of the RF IC device 201 to be connected to the via hole 202 (S403). Herein, the desired metal wiring layer 203 may be formed by first applying an insulating material (for example, dry film or photosensitive film) on both surfaces of the RF IC device 201, removing the insulating material in a predetermined pattern along a region in which the metal wiring layer is formed, by using a mask and a photolithography, forming the metal (for example, copper) wiring layer in an opened region of both surfaces of the RF IC device 201 formed by the removal of the insulating material by using the electroplating method, and the like, and then removing the insulating material remaining on both surfaces of the RF IC device 201.

By the above description, when the formation of the metal wiring layer 203 is completed, as illustrated in FIG. 5D, the electronic components 204a to 204c are mounted on the metal wiring layer 203 of one side of the RF IC device 201 (S404). In this case, as described above, in order to mount the electronic components 204a to 204c on the metal wiring layer 203 of the one side of the RF IC device 201, the method according to the exemplary embodiment of the present invention further includes forming the bump 211 on the metal wiring layer 203 of the one side of the RF IC device 201. In this case, as the bump 211, a general solder bump may be used.

When the mounting of the electronic components 204a to 204c is completed, the one side of the RF IC device 201 in which the electronic components 204a to 204c are mounted is molded with the molding material 205 (S405). In this case, as the molding material 205, a thermosetting resin or a thermoplastic resin may be used.

When the molding is completed, as illustrated in FIG. 5E, the auxiliary substrate 206 on which the through hole 206v having a predetermined size for mounting the other electronic components 207a and 207b therein is formed is coupled with the other surface of the RF IC device 201 (S406).

Herein, in order to couple the auxiliary substrate 206 with the other surface of the RF IC device 201, the method according to the exemplary embodiment of the present invention further includes forming the bump 212 on the metal wiring layer 203 of the other surface of the RF IC device 201. In this case, as the bump 212, a general solder bump may be used.

By doing so, when the coupling of the auxiliary substrate 206 with the RF IC device 201 is completed, the other electronic components 207a and 207b are mounted on the other surface of the RF IC device 201 through the through hole 206v of the auxiliary substrate 206 (S407). In this case, in order to mount the other electronic components 207a and 207b on the other surface of the RF IC device 201, the method according to the exemplary embodiment of the present invention further includes forming the bump 213 on the metal wiring layer 203 of the other surface of the RF IC device 201 corresponding to the region of the through hole 206v of the auxiliary substrate 206. In this case, as the bump 213, the general solder bump may be used.

Herein, as described above, in order to couple the auxiliary substrate 206 with the RF IC device 201, the process of forming the bump 212 and the process of forming the bump 213 to mount the other electronic components 207a and 207b through the through hole 206v of the auxiliary substrate 206 may be performed separately or simultaneously.

As set forth above, according to the method of manufacturing an RF module according to the exemplary embodiments of the present invention, it is possible to design the IC circuit of the wafer level chip scale package (WLCSP) and design the I/O pitch with the sufficient degree of freedom by allowing the RF IC device to perform the function of the main circuit substrate and introducing the auxiliary substrate to secure the flexibility of I/O implementation.

Although the exemplary embodiments of the present invention have been disclosed for illustrative purposes, the present invention is not limited thereto, but those skilled in the art will appreciate that various modifications, additions and substitutions are possible, without departing from the scope and spirit of the invention as disclosed in the accompanying claims. Therefore, the protection scope of the present invention must be analyzed by the appended claims and it should be analyzed that all spirits within a scope equivalent thereto are included in the appended claims of the present invention.

What is claimed is:

1. An RF module, comprising:
an RF IC device serving as a main substrate and provided with a via through which upper and lower surfaces thereof are connected to each other;
an electronic component mounted on the upper surface or the lower surface of the RF IC device;
a molding material having the electronic component sealed therein to protect the electronic component and formed on the upper surface or the lower surface of the RF IC device; and
an auxiliary substrate coupled with the upper surface or the lower surface of the RF IC device and providing a place at which other electronic components other than the electronic component sealed in the molding material are mounted.

2. The RF module according to claim 1, wherein the auxiliary substrate is provided with a through hole having a predetermined size to mount the other electronic components therein.

3. A method of manufacturing an RF module, comprising:
a) preparing an RF IC device serving as a main substrate;
b) forming a via hole, through which upper and lower surfaces of the RF IC device are connected to each other, in the RF IC device and filling the via hole with a conductive material;
c) forming metal wiring layers on both surfaces of the RF IC device, respectively, to be connected to the via hole;
d) mounting an electronic component on the metal wiring layer of one side of the RF IC device;
e) molding the one side of the RF IC device, on which the electronic component is mounted, with a molding material;
f) coupling an auxiliary substrate provided with a through hole having a predetermined size to mount other electronic components therein with the other surface of the RF IC device; and
g) mounting the other electronic components on the other surface of the RF IC device through the through hole of the auxiliary substrate.

4. The method according to claim 3, wherein in the step b), the via hole is formed by dry etching using excimer laser or CO₂ laser.

5. The method according to claim 3, wherein in the step b), the conductive material filled in the via hole is copper or silver.

6. The method according to claim 5, wherein the copper is filled in the via hole by electroplating.

7. The method according to claim 3, further comprising:
in order to mount the electronic component on the metal wiring layer of the one side of the RF IC device in the step d), forming a bump on the metal wiring layer of the one side of the RF IC device.

8. The method according to claim 3, wherein the molding material in the step e) is a thermosetting resin or a thermoplastic resin.

9. The method according to claim 3, further comprising:
in order to couple the auxiliary substrate with the other surface of the RF IC device in the step f), forming the bump on the metal wiring layer of the other surface of the RF IC device.

10. The method according to claim 3, further comprising:
in order to mount the other electronic components on the other surface of the RF IC device in the step g), forming the bump on the metal wiring layer of the other surface of the RF IC device corresponding to a region of the through hole of the auxiliary substrate.
